(19) United States
(12) Patent Application Publication
(10) Pub. No.: US 2011/0000224 A1
(43) Pub. Date: Jan. 6, 2011

(54) METAL-CORE THERMOELECTRIC COOLING AND POWER GENERATION DEVICE

(76) Inventors: Uttam Ghoshal, Austin, TX (US); Ayan Guha, Austin, TX (US)

Correspondence Address: LESTER H. BIRNBAUM, 6 OAKMOUNT COURT, SIMPSONVILLE, SC, 29681, US

(21) Appl. No.: 12/736,126

(22) PCT Filed: Mar. 11, 2009
(86) PCT No.: PCT/US09/01542

§ 371 Date: Sep. 13, 2010

Related U.S. Application Data
(60) Provisional application No. 61/069,974, filed on Mar. 19, 2008.

(51) Int. Cl. F25B 21/02; H01L 29/66; H01L 21/28

(52) U.S. Cl. 62/3.7; 257/470; 438/54; 257/E29.347; 257/E21.158

(57) ABSTRACT

In various embodiments of the present invention, a thermoelectric device is provided. The thermoelectric device includes one or more thermoelements provided for transferring heat across the ends of the thermoelectric device. A method for making the thermoelectric device includes forming a metal substrate, and depositing one or more thermoelectric films on the metal substrate. Thereafter, one or more bumps are provided on one of the one or more thermoelectric films. Deposition of the one or more thermoelectric films on the metal substrate and the provision of the one or more bumps on the thermoelectric film result in the formation of a thermoelement.

### BACKGROUND

The present invention relates to the field of thermoelectric devices. More specifically, the present invention relates to thin film thermoelectric devices.

Thermoelectric devices are solid-state devices that convert thermal energy into electrical energy in the presence of a temperature gradient. While the conversion of temperature difference into electricity is due to the Seebeck effect, an inverse reciprocal effect that enables the transfer of heat when electrical energy is provided is known as the Peltier effect. Thus, a thermoelectric cooling device (also known as a Peltier device) is a solid state heat pump, which transfers heat from one location to another in the presence of an electrical current. In the power generation mode, a thermoelectric device can generate electricity if a temperature gradient is applied across it. Thermoelectric devices have tremendous potential in providing eco-friendly solutions to energy and cooling needs.

Conventional thermoelectric cooling devices use one or more thermoelectric couples, in conjunction with a power source, for cooling purposes. Typically, such cooling devices have a low cooling density due to their poor material properties, large form factors, and soldered interfaces at cooling boundaries. The cooling power of a thermoelectric cooler is proportional to the power factor P, (P=S²σ, where S is the Seebeck coefficient and σ is the electrical conductivity). In addition, the cooling power of the thermoelectric cooler is inversely proportional to the transport length l. Conventional thermoelectric cooling devices have a long transport length (˜1-3 mm) and low maximum cooling power (˜5 W/cm²). Ideally, a good thermoelectric material should have a large Seebeck coefficient and high electrical conductivity to minimize Joule heating. Additionally, it should have low thermal conductivity to maintain large temperature gradients. These criteria help to define the thermoelectric figure of merit, Z (Z=S²σ/λ, where S is the Seebeck coefficient of material, σ is the electrical conductivity, and λ is the thermal conductivity of the material).

Another parameter for evaluating the performance of thermoelectric materials is a dimensionless quantity defined as ZT. Since the discovery of semiconductors as useful thermoelectric materials in early 1950s, a large number of materials have been investigated in an attempt to increase the parameter ZT. Among the materials discovered, compound semiconductors based on Bismuth Telluride (ZT close to 1) are best suited as thermoelectric materials for room temperature applications. Recent breakthroughs in super-lattice and nano-structured materials have resulted in obtaining high values for ZT, but these are yet to be incorporated in commercial coolers. One of the methods for increasing the ZT of these compound semiconductors involves depositing thin films under suitable conditions. Thin film deposition enables optimization of the relevant parameters. This optimization can be achieved by sequentially growing different thin films of different materials without contaminating the interfaces. Thin film deposition also uses less thermoelectric materials than conventional film deposition, thereby reducing the cost of the thermoelectric devices. Thin film deposition provides flexibility to the process of manufacturing vertical or lateral thermoelectric coolers. Further, lateral thermoelectric coolers are suitable for high cooling densities. Due to short transport lengths, thin film thermoelectric cooling devices have a fast time response, which makes them suitable for polymerase chain reaction (PCR) and transient cooling applications.

Thin film thermoelectric cooling devices are thus more economical, reliable and efficient alternatives to conventional thermoelectric cooling devices. Since the cooling power of the thermoelectric cooler is inversely proportional to the transport length of the cooling elements, thin film thermoelectric elements are suitable for high cooling densities (>100 W/cm²). Removal of a large amount of heat from the cold side of the thermoelectric cooler results in the dissipation of large densities of heat (>200 W/cm²) at the hot side of the thermoelectric cooler. The inability of the thermoelectric cooler to spread or transport heat from the hot side significantly limits the performance of thin film thermoelectric cooling devices. Managing such large densities of heat is the foremost challenge in realizing the true potential of thin film thermoelectric cooling devices.

In the past few decades, rapid progress in the field of semiconductor device manufacturing has resulted in a large number of thin film thermoelectric cooling devices being implemented on Silicon (Si) or Gallium Arsenide (GaAs) substrates. However, the ease of processing thermoelectric materials by using standard techniques in the deposition of films on semiconductor substrates is offset by the fact that these films do not spread heat adequately when formed using standard techniques. The process of patterning and etching thermoelectric films usually contaminates the surfaces that are crucial for the performance of these thin film thermoelectric cooling devices. To manage heat densities by using fans and heat sinks for air cooling, it is helpful to fabricate a thin film thermoelectric cooling device with thick thermoelectric legs. Etching thick thermoelectric films consumes a considerable amount of time, involves prolonged exposure to chemicals, and degrades the properties of the films. Since different types of films etch differently, it is difficult, if not impossible, to etch a compound stack of thermoelectric films. Optimization of a thermoelectric film by changing its composition or type generally requires a new etching process. Restrictions imposed by etching significantly limit the process of material development and incorporation of novel films for the enhanced performance of these thin film thermoelectric cooling devices. Integration steps of etching, patterning, and the like, also result in an increase in contact resistance and packaging complexity of the thin film thermoelectric cooling devices. Consequently, there is a need for an improved thin film thermoelectric device and a method for manufacturing the thin film thermoelectric device that incorporates the advantages of thin film thermoelectric materials, while addressing their current drawbacks.

### SUMMARY

In an embodiment of the present invention, a method for making a thermoelectric device includes forming (alternatively referred to as processing) a metal substrate, and depositing a thermoelectric film (alternatively referred to as a thin thermoelectric film) on the metal substrate. Thereafter, one or more bumped structures (alternatively referred to as bumps) are provided on the thermoelectric film. The deposition of the thermoelectric film on the metal substrate and the provision of the one or more bumps on the thermoelectric film result in the formation of a thermoelement. The thermoelectric film can be a p-type film (excess holes) or an n-type film (excess electrons), depending on the majority carriers in the film. While a single doped target is usually employed for p-type deposition, the elementary targets can be co-deposited to deposit an n-type thermoelectric film on the metal substrate.

The thermoelectric device in accordance with an embodiment of the invention includes one or more thermoelements, usually alternating a p-type element and an n-type element, which are connected by metallic interconnects. In the presence of a DC electrical current, these thermoelements transfer heat across the two ends of the thermoelectric device. In an embodiment of the present invention, the thermoelements include a metal substrate, which facilitates the dissipation of the extracted heat and the joule heat from a cold side of the thermoelectric device to a heat sink located at a hot side of the thermoelectric device. Since the thermoelectric film is directly deposited on the metal substrate, both the electrical and thermal contact resistances are minimized. The metal substrate manages high thermal flux in the hot side by spreading the heat more efficiently than a conventional semiconductor substrate, and by providing a large surface area to minimize soldering losses.

In accordance with an embodiment, the thermoelements include one or more bumps. These bumps define the electrical and thermal contact area of the thermoelectric film. The maximum current (Iₘₐₓ) that can enable cooling of a thermoelectric element is defined as Iₘₐₓ=ST_{c}/R, where S is the Seebeck coefficient, T_{c} the temperature of the cold side, and R the electrical resistance. The cross section area of the one or more bumps controls the electrical resistance of the thermoelectric element, thereby controlling the Iₘₐₓ and the operating current of an associated thermoelectric leg. A typical thermoelectric device has an Iₘₐₓ that is close to five amperes. The thermoelements can be tailored to work at current levels close to Iₘₐₓ through proper bump geometry. Further, the one or more bumps decrease thermal conductance between the top and bottom sides of the device, thereby maintaining the desired temperature difference. Thus, cross-section area of the bumps is configured to provide a predefined electrical and thermal resistance to the thermoelement.

### BRIEF DESCRIPTION OF THE DRAWINGS

The preferred embodiments of the present invention will hereinafter be described in conjunction with the appended drawings that are provided to illustrate and not to limit the invention, wherein like designations denote like elements, and in which:

FIG. 1 illustrates a cross-sectional view of a conventional thermoelectric cooling device;

FIG. 2 illustrates a cross-sectional view of a thermoelement, in accordance with various embodiments of the present invention;

FIG. 3 illustrates a cross-sectional view of a thermoelectric cooling device, in accordance with an embodiment of the present invention;

FIG. 4 illustrates a top view of a thermoelectric cooling device, in accordance with an embodiment of the present invention;

FIG. 5 is a flow chart illustrating a method for creating a thermoelectric cooling device, in accordance with various embodiments of the present invention;

FIG. 6 is a flow chart illustrating a method for creating a metal substrate, in accordance with various embodiments of the present invention; and

FIG. 7 is a flow chart illustrating a method for depositing a thin thermoelectric film on a metal substrate, in accordance with various embodiments of the present invention.

### DETAILED DESCRIPTION OF THE INVENTION

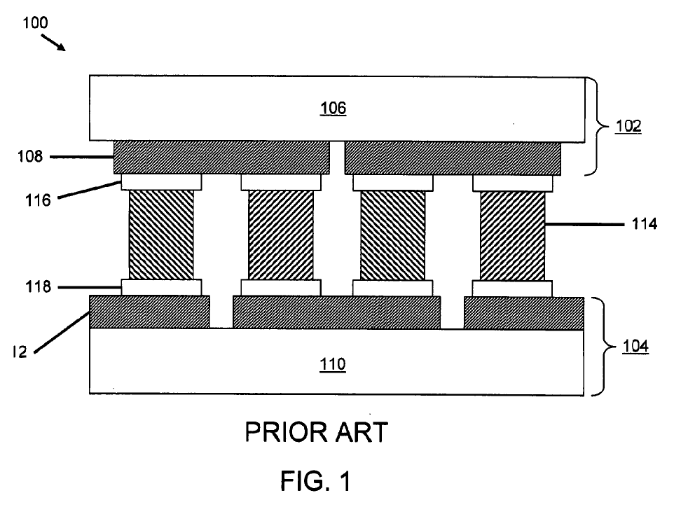

FIG. 1 illustrates a cross-sectional view of a conventional thermoelectric device 100.

Conventional thermoelectric devices have one or more thermoelements provided between layers, in conjunction with a DC current source. Conventional thermoelectric device 100 includes a first part 102 and a second part 104. First part 102 includes a first layer 106, which is made of a material with a high thermal conductance and a low electrical conductance. Typically, first layer 106 is made of aluminum nitride or thin alumina ceramic. First part 102 also includes a second layer 108, which is a metallic interconnect with a high thermal and electrical conductance, connecting first layer 106 to one or more thermoelements. Typical examples of such materials include, but are not limited to, copper, nickel, and aluminum. Like first part 102, second part 104 includes a third layer 110 and a fourth layer 112. Third layer 110 has a similar function as first layer 106, and is made of a material with a high thermal conductance and a low electrical conductance. Typically, third layer 110 is a ceramic plate, an aluminum nitride substrate or a metal-core printed circuit board. Further, fourth layer 112 is a metallic interconnect similar to second layer 108, and provides electrical connection between the one or more thermoelements. For an efficient heat transfer to third layer 110, fourth layer 112 is also made of a material with a high thermal conductance. Typical examples of such materials include, but are not limited to, copper, nickel, and aluminum.

In conventional thermoelectric devices, one or more thermoelements are provided between first part 102 and second part 104. For the purpose of this particular description, they are indicated by thermoelements such as 114. In a conventional device, thermoelements are made of a bulk thermoelectric material, with compositions close to a pseudo-binary system such as Bismuth Antimony Telluride Bi(2-x)Sb(x)Te(3) for the p type and Bismuth Tellurium Selenide Bi(2)Te(3-y)Se(y) for the n type. In thin film cooling devices, thermoelement 114 can be a semiconductor substrate (typically Silicon or Gallium Arsenide) including a sputter-coated or a molecular beam epitaxy (MBE) grown thermoelectric film. Thermoelement 114 includes either an n-type thermoelement or a p-type thermoelement. When a current flows through thermoelement 114, heat is extracted from the end of thermoelement 114 which is connected to first part 102. The extracted heat and the joule heat from the flowing current is dissipated at the end of thermoelement 114 which is connected to second part 104. Alternating the p-type and n-type thermoelements is desirable to ensure that the temperature of first part 102 is less than that of second part 104 due to the current flowing from first part 102 to second part 104.

Thermoelement 114 is connected to first part 102 and second part 104 with metal solders. In accordance with an embodiment, these metal solders are represented in FIG. 1 as a metal solder 116 and a metal solder 118. Typical examples of metal solders include, but are not limited to, tin solders, bismuth solders, and lead solders.

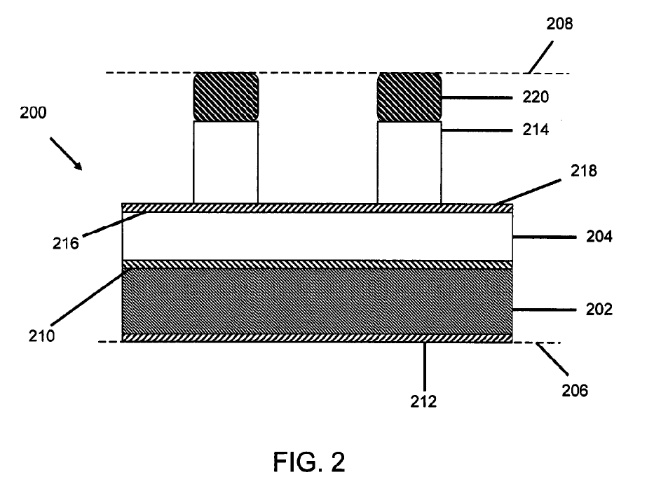

FIG. 2 illustrates a cross-sectional view of a thermoelement 200, in accordance with various embodiments of the invention. Thermoelement 200 includes a metal substrate 202, a thermoelectric film 204, and one or more bumps. For the purpose of this particular description, the one or more bumps are indicated by a bump 214.

In accordance with an embodiment, thermoelement 200 includes metal substrate 202 to facilitate the dissipation of extracted and joule heat to a heat sink of thermoelement 200 (not shown in FIG. 2). In an exemplary embodiment, metal substrate 202 can be made of aluminum, tungsten, nickel, molybdenum or copper. The metal substrate can be of any thickness as long as it provides mechanical stability to the thermoelectric film and the bumps. As a result, thin aluminum substrates that make the thermoelement cheaper than those available in the market can be used. At present, thermoelectric thin film coolers depend on semiconductor substrates on which metal interconnects are deposited. This creates a number of thermal interfaces between the thermoelectric film and the heat sink. In accordance with the exemplary embodiment of the present invention described herein, the number of interfaces is reduced to a minimum to enable an efficient heat flow to the heat sink.

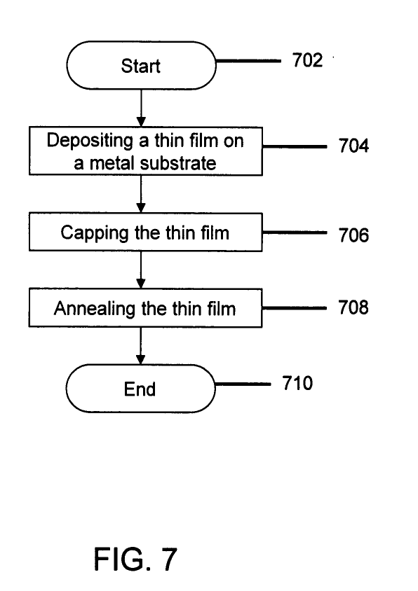

Thin thermoelectric films such as thermoelectric film 204 are characterized by thickness of the thermoelectric films. In an embodiment of the present invention, the thickness of a stack of the thin thermoelectric films is between 1.0 micron and 10 micron. Due to the small thickness, the thin thermoelectric films are preferably deposited on a substrate using methods such as plasma vapor deposition sputtering, electroplating, etc. unlike conventional thermoelectric films. The thin thermoelectric films can be integrated on a substrate such as Silicon and Gallium Arsenide that results in improved packing. In an embodiment of the present invention, the thin thermoelectric films are deposited on metal substrates to provide metal core thin film thermoelectric coolers. The metal core thin film thermoelectric coolers have high cooling density and fast time response. The method of depositing a thin thermoelectric film on a metal substrate has been described in conjunction with FIG. 7.

Thermoelectric film 204 comprises either an n-type semiconductor material or a p-type semiconductor material. For room temperature applications, the preferred thermoelectric materials are optimal compositions of Bi2Te3-Sb2Te3-Bi2Se3 pseudo-ternary systems. In one embodiment, thermoelectric film 204 is a sputter deposited film of the compound mentioned above. Some other examples of thermoelectric film 204 include, but are not limited to, thin films of: lead telluride (PbTe); antimony telluride (SbTe); indium antimonide (InSb); gallium indium antimonide (GaInSb); indium arsenide (InAs); cobalt, nickel, or iron antimonide ((Co, Ni, Fe)Sb3); and yetterbium aluminide (YbAl3). In another exemplary embodiment, thermoelectric film 204 can be a silicon (Si) nano-wire deposited on metal substrate 202. In accordance with an embodiment, layered thermoelectric thin films include metallic thermoelectric films with a high power factor, for example, YbAl3, and sandwiched high Seebeck films, for example, bismuth telluride (BiTe) and lead telluride (PbTe). Thus, in an exemplary embodiment, thermoelement 200 may include multiple thermoelectric films deposited over metal substrate 202, thereby forming a layered structure with an engineered Seebeck coefficient.

When a current flows through thermoelement 200, heat is transferred from a first end 206 to a second end 208 of thermoelement 200. A first layer 210, at the top of metal substrate 202, serves as a wetting layer for thermoelectric film 204. This layer improves the adhesion of the film to the metal substrate, thereby reducing the contact resistance. This layer can be omitted when the thermoelectric film adheres well to the metal substrate. Typical examples of first layer 210 include, but are not limited to, titanium (Ti), titanium tungsten (TiW), nickel (Ni) and platinum (Pt) layers. In accordance with an embodiment, a second layer 212, on one side of metal substrate 202, is a wetting layer for a solder with which metal substrate 202 is soldered to a metallic interconnect such as 108 of FIG. 1. Second layer 212 protects this side of metal substrate 202 from oxidizing and provides a surface for assembly. Typical examples of second layer 212 include, but are not limited to, TiW, Ni, Pt and gold (Au) layers.

Thermoelement 200 includes one or more bumps, such as bump 214, which are placed on first side 216 of thermoelectric film 204. Bump 214 provides electrical and thermal contact to thermoelectric film 204 and controls the thermal flux passing through thermoelement 200. Thus, bump 214 defines the electrical and thermal contact area of thermoelectric film 204. Cross section area of bump 214 controls the electrical resistance of thermoelement 200. Further, the maximum current that can enable cooling of thermoelement 200 is inversely proportional to electrical resistance of thermoelement 200. Thus, by varying the cross section area of bump 214, electrical resistance and the maximum current in thermoelement 200 can be varied. Similarly, it should be apparent to a person skilled in the art that the thermal resistance increases when cross section area of bump 214 or the number of the bumps decreases. Therefore, cross-section area of bump 214 can be configured to provide a predefined electrical and thermal resistance to thermoelement 200.

In an exemplary embodiment, the one or more bumps are made of, but are not limited to, materials such as copper, nickel, gold, and tin. In another exemplary embodiment, these bumps are made of a solder deposited by the metal jet process.

In accordance with an embodiment, a barrier layer 218 is present between bump 214 and thermoelectric film 204. Barrier layer 218 prevents thermal diffusion of the bump material into thermoelectric film 204 during the soldering process or over a long period of time. Typical examples of such barrier layers include, but are not limited to, aluminum (Al), nickel (Ni), tantalum (Ta), tantalum nitride (TaN), tungsten (W) and Titanium Tungsten (TiW) layers.

The metal bumps are coated with a solder layer 220. The reflow of solder layer 220 enables the thermoelectric element to be attached to the package. Examples of solder layer 220 include, but are not limited to, electroplated tin (Sn), tin bismuth (SnBi), and indium (In).

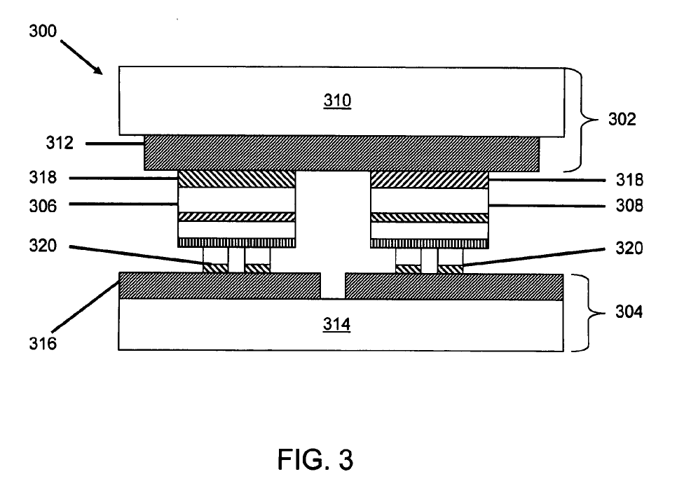

FIG. 3 illustrates a cross-sectional view of a thermoelectric cooling device 300, in accordance with an embodiment of the present invention. In addition to the elements described with reference to FIG. 2, thermoelectric cooling device 300 includes a first part 302, a second part 304, an n-type thermoelement 306, and a p-type thermoelement 308.

In accordance with an embodiment of the present invention, first part 302 includes a first layer 310. First layer 310 is made of a thermally conducting but electrically insulating material, for example, aluminum nitride and diamond substrates. In another exemplary embodiment, first layer 310 is a metal-core printed circuit board (PCB) with an aluminum core and anodized aluminum as the insulating layer. A typical example of the metal-core PCB is Anotherm substrates. First part 302 further includes a second layer 312, which is a metallic interconnect and connects the thermoelements. In a metal-core PCB, conducting tracks made of electroplated copper (Cu), Cu/Ni or silver (Ag) form second layer 312. In an exemplary embodiment, second layer 312 is made of, for example, copper, aluminum, silver, nickel, gold, and the like.

Second part 304 includes a third layer 314 that is functionally similar to first layer 310. Third layer 314, which is an electrical insulator but a thermal conductor, is made of one of, but not limited to, ceramic, aluminum nitride, sapphire, and artificial diamond. Like first layer 310, third layer 314 can also be a metal-core printed circuit board. Second part 304 also includes a fourth layer 316, which is a metallic interconnect with similar functionalities as second layer 312. Like second layer 312, fourth layer 316 is made of one of, but not limited to, copper, aluminum, nickel, silver, and gold.

Thermoelectric cooling device 300 includes one or more thermoelements provided between first part 302 and second part 304. For the purpose of this particular description, the one or more thermoelements are indicated by n-type thermoelement 306 and p-type thermoelement 308. N-type thermoelement 306 comprises n-type thermoelectric films (films with excess electrons), and p-type thermoelement 308 comprises p-type thermoelectric films (films with excess holes). Thermoelements 306 and 308 are attached to second layer 312 and fourth layer 316 through metal solders 318 and 320, respectively. In accordance with an embodiment, metal solders 318 and 320 are one of tin, bismuth and lead solders.

N-type thermoelement 306 and p-type thermoelement 308 include a metal substrate, one or more thermoelectric films, and one or more bumps (described in detail in conjunction with FIG. 2). In this exemplary embodiment, the metal substrate (202 of FIG. 2) not only provides support to the thin thermoelectric films, but also helps in the electrical as well as thermal conduction. In accordance with an embodiment, each thermoelement is coated with a solder on both ends. The solder can be a replacement for thick thermoelectric legs of traditional devices. Since thermoelectric films are more efficient than bulk thermoelectric legs and are economical to produce, this replacement is beneficial not only for improving the performance but also for reducing the manufacturing cost of the device. The thin film deposition enables Seebeck engineering of the layers, thereby improving the performance significantly. The thermoelectric cooling device as described in this embodiment has a faster time response, higher cooling density and higher efficiency, as compared with a traditional thermoelectric device.

While metal substrates are extremely useful in minimizing the electrical and thermal losses, soft substrates, such as Al and Cu, exhibit a significant “burring” (or deformation) when diced with a diamond saw. Any burr projecting out of the substrate can interfere with the assembly of the thermoelements, and in some cases, cause a thermal short between the top and bottom layers. While judicious choice of diamond blade and saw speed can minimize the burr height, it is almost negligible (less than one micron) when advanced dicing techniques such as laser cutting are introduced. Burring can also be eliminated by carrying out one of pre-grooving the substrates before a thin film deposition, chemically etching the edges while protecting the active area with photoresist, and creating spacers in the packaging substrate. In an exemplary embodiment, the spacers can be in the form of metallic pedestals in layers 312 and 316.

While integrated thin film thermoelectric devices on semiconductor substrates generally cannot dissipate heat efficiently, thermoelectric cooling device 300 can provide cooling densities of about 100 watts per square centimeter and heat rejection densities of about 400 watts per square centimeter. The high cooling density is achieved by using thermoelectric films that provide enhanced cooling power. Further, the thermal losses due to inefficient spreading of heat is minimized through the deposition of Seebeck engineered thin films.

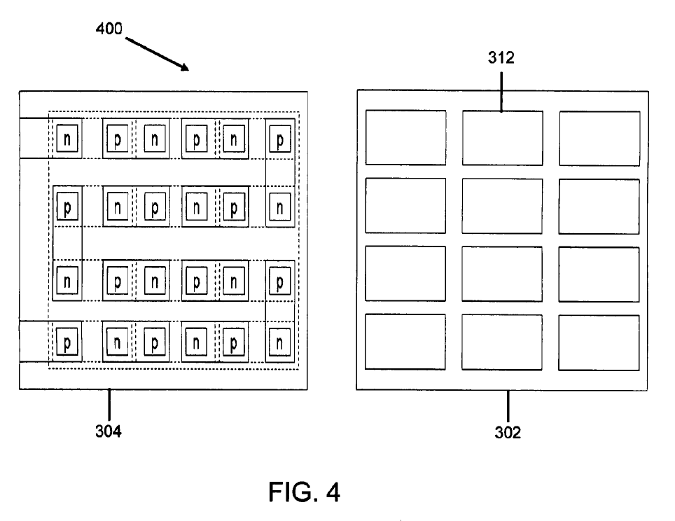

FIG. 4 illustrates a top schematic view of a fully packaged thermoelectric cooling device 400, in accordance with another embodiment of the present invention.

Thermoelectric cooling device 400 includes first part 302, second part 304, and the thermoelements. First part 302 is shown removed from second part 304 to illustrate second part 304. The thermoelements are assembled in a particular order to enable the flow of current across thermoelectric cooling device 400. The arrangement illustrates alternate n-type and p-type thermoelements connected to second part 304. Both first part 302 and second part 304 comprise insulating substrates provided with metallic interconnects for the purpose of assembling the thermoelements. The majority of common bulk thermoelectric coolers that are available commercially have about 127 thermoelectric couples. Second part 304 can not only accommodate a similar number of thermoelectric couples, but depending on the cooling requirements, it can be tailored to host any number of thermoelectric couples. While second part 304 provides a platform and bottom electrical connection for the purpose of assembling the thermoelements, first part 302 provides the top cover and electrical contacts through second layer 312.

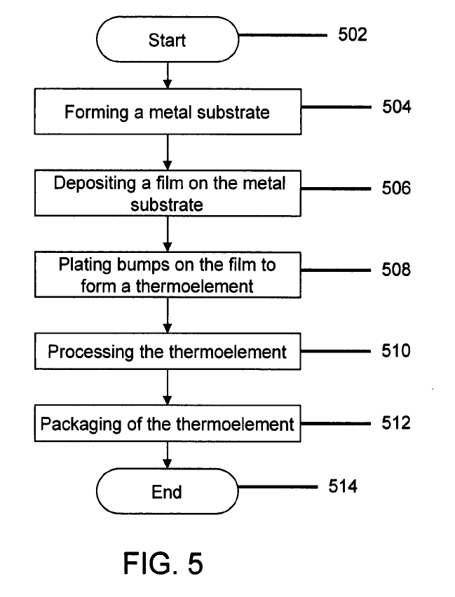

FIG. 5 is a flow chart illustrating a method for creating a thermoelectric cooling device, in accordance with various embodiments of the present invention.

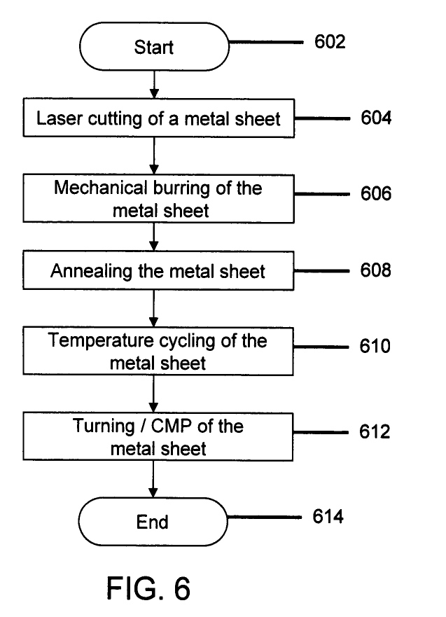

The method starts at step 502. At step 504, metal substrate 202, herein also referred to as a wafer, is formed (alternatively referred to as processed). In accordance with an embodiment, a metal sheet is cut using a laser to form metal substrate 202. In an exemplary embodiment, the metal sheet is one of, but not limited to, aluminum, copper, tungsten, and molybdenum sheets. While metal substrate 202 can be circular, there is no restriction to its size or shape. The size and shape of metal substrate 202 is governed by the choice of process steps for thin film deposition and electroplating of bumps. Since metal substrate 202 is exposed to high temperatures during the thermoelectric film deposition, anneal and solder reflow processes, it is important to take preventive steps in the beginning to remove possible stresses. At high temperatures, the inbuilt stresses can warp the wafer, thereby creating problems due to non-uniformity in the subsequent process steps. The residual stresses in a substrate can be removed by annealing it to high temperatures while subjecting it to the pressure between two flat surfaces. After this tempering step, the metal substrate 202 undergoes a smoothening process. The top surface of metal substrate 202 can be smoothened by either Chemical Mechanical Planarization (CMP) polishing or single-point diamond turning. Since grown thermoelectric films have a rough topography, the smoothening of the substrate is critical for thick thermoelectric films. Smoothening may not be necessary when the average surface roughness of the substrate is less than or equal to 0.1 micron. The formation of metal substrate 202 is described in detail in conjunction with FIG. 6.

At step 506, thermoelectric film 204 is deposited over metal substrate 202. The deposition process is one of, but not limited to, plasma vapor deposition, e-beam sputtering, electroplating, molecular-beam epitaxy, and metal-organic chemical vapor deposition. In an embodiment, thermoelectric film 204 can include, but is not limited to one or more of the group consisting of Bi chalcogenides (Bi(0.5)Sb(1.5)Te(3), Bi(2)Te(3), Bi(2)Se(3), CsBi(4)Te(6), KBiTe(3), etc.), Pb chalcogenides (PbTe, PbEuTe, PbSnTe, and the like), YbAl(3), CeAl(3), InSb, Ga(0.03)In(0.97)Sb, Sb(2)Te(3), HgCdTe, Skutteridites (CoSb(3), Fe(0.2)Co(0.8)Sb(3), etc.), Si nano-wires, and SiGe. The thickness of the thin thermoelectric films can vary from 1.0 micron to 10 micron. To maintain the improved Seebeck and low thermal conductivities observed in thin films, thick films can be grown by stacking metal layers, such as Al, Pt, Ni, Ti, and TiW, in between the thin films. While thin films can support high cooling densities, they are more suitable for low heat flux densities.

The performance of the films can be increased significantly by depositing different types of thin films sequentially such that the Seebeck coefficient is graded across the thermoelement. For n-type films, this can be achieved by depositing a YbAl (3)/Bi or Pb Chalcogenide/YbAl(3) sandwich. A similar gradation can be achieved in p-type films by controlling the diffusion of Pt across the thin film interfaces. Since an ideal thermoelectric film should have an electron-lattice phonon-glass structure, phonon blocking layers, for example, layers made from indium, can improve the performance of the films mentioned above. Since the deposited thermoelectric films tend to form clusters and large grains, such films can be homogenized by rapid quenching during the anneal cycle. By directly depositing the films on metal substrates and avoiding complicated chemical etching steps, all the techniques mentioned above can be implemented to create cooling devices. Multiple thermoelectric layers can reduce the thermal conductivity of the thermoelement and provide a smooth gradient for a change in the Seebeck coefficient at the interfaces.

Before depositing the thermoelectric film, first layer 210 is preferably deposited on the top of metal substrate 202. First layer 210 acts as a wetting layer for the thermoelectric film, improving adhesion and decreasing the contact electrical and thermal resistance of the film. Typical examples of first layer 210 include, but are not limited to, thin films of Pt, Ti, TiW and Al. In accordance with an embodiment, second layer 212 is also deposited on the other side of metal substrate 202. Second layer 212 protects the surface of metal substrate 202 and provides a wetting layer for the solder. This thin metal layer can be one of, but is not limited to, sputter coated Ti and Pt, sputter coated bilayers of TiW/Au, Ni/Au, and Cr/Au, electroplated Cu/Au, and solder.

After the thermoelectric film deposition, in some cases, barrier layer 218 is deposited on thermoelectric film 204. Barrier layer 218, preferably deposited along with the thermoelectric film (without breaking the vacuum), prevents oxidation of the thermoelectric film. Barrier layer 218 also provides a barrier for the thermal diffusion of the bump material. In an exemplary embodiment, barrier layer 218 is made of one of, but is not limited to, Ni, Pt, Cr, and Al. After depositing barrier layer 218, thermoelectric film 204 is subjected to annealing to homogenize its Seebeck, electrical and thermal properties. Annealing the film with barrier layer 218 on the top inhibits grain growth during the annealing process, thereby keeping the film surface smooth. The deposition of thermoelectric film 204 on metal substrate 202 is described in detail in conjunction with FIG. 6.

At step 508, one or more bumps are provided on first side 216 of thermoelectric film 204. These bumps are critical in controlling the electrical and thermal resistance of the film. In accordance with an embodiment, these bumps are created by using the standard flip chip technology, which involves metal deposition through electroplating or electro-less plating techniques. Usually, an under bump metallization is performed to sensitize the surface for the growth of these bumps. Typical examples of these bumps include, but are not limited to, electroplated copper bumps capped with electroplated Sn or electro-less Au, electro-less Ni topped with Au, electro-less W topped with Au, and electroplated solder. For high temperature applications, a refractory metal bump such as tungsten is more suitable than Cu bumps.

Depositing thermoelectric film 204 on metal substrate 202 and providing one or more bumps on thermoelectric film 204 essentially completes thermoelement 200. Thereafter, these elements are diced or separated by etching the metal substrate from the backside of the metal wafer to form packaged thermoelectric cooling device 400, as shown in FIG. 4.

At step 510, if required, thermoelement 200 may be processed further after dicing. Dicing soft metal substrates such as Cu and Al with a diamond saw creates a burr along the dicing edges. This deformation (or burr) is absent in the refractory metal substrates such as W and Mo. For soft metals, such as aluminum and copper, carbon dioxide laser cutting provides a desired surface finish with the minimum burr height and precise quality of the cut. Another alternative can be dicing with water jets where the material is cut without interfering with its internal structure, since there is no heat affected zone.

In addition to the above, a suitable choice of diamond saw and saw speeds can reduce the burr height, and the substrate can be engineered in a way such that this small burr does not affect the performance of the thermoelement. One such method involves mechanically cutting grooves (about 100 micron deep) and removing the burr through polishing by using the CMP or diamond turning processes. Laser cutting along the grooves creates a burr that is sub-terrain and does not interfere with the packaging process.

In accordance with another embodiment, the grooves can be created by chemical etching. After patterning metal substrate 202 with a photoresist layer, it can be subjected to standard metal etchants. Various examples of standard metal etchants include, but are not limited to, phosphoric acid, hydrochloric acid, nitric acid, and acetic acid for etching aluminum. Some other examples of standard metal etchants include sulphuric acid, ferric chloride and nitric acid for etching copper. The burr can be removed post-dicing when the wafer is diced with a layer of photoresist and individual dies are exposed to etching chemicals.

In accordance with another embodiment, an ultra-violet light curable polyimide tape is attached to the surface of the metal substrate 202 with the bumps to protect the surface, and the metal substrate is etched from the backside, and individual dies are singularized. Various examples of standard metal etchants include, but are not limited to, phosphoric acid, hydrochloric acid, nitric acid, and acetic acid for etching aluminum. Some other examples of standard metal etchants include sulphuric acid, ferric chloride and nitric acid for etching copper. The tape is then cured under UV light and the thermoelement dies 200 separated out for the packaging step 512.

In accordance with another embodiment, the thermoelement dies 200 are separated by mechanical stamping of the metal substrate 202.

Step 512 involves packaging of the diced thermoelements. For example, in thermoelectric cooling device 300, n-type thermoelement 306 and p-type thermoelement 308 are provided between first part 302 and second part 304. Since both ends of the thermoelement are either solder plated or can be soldered, the thermoelement can pass through a reflow oven. Passing the solders on both sides of the thermoelement through the reflow oven essentially completes the process of manufacturing the thermoelectric cooling device. When two different solders are used, the thermoelements can be assembled on one plate with the solder that melts at a high temperature, followed by attaching the second plate with a low melting solder. A top view of the fully packaged device is shown in FIG. 4. The process ends at step 514.

FIG. 6 is a flow chart illustrating a method for creating metal substrate 202, in accordance with various embodiments of the present invention.

The method starts at step 602. At step 604, a metal sheet is cut using a laser. The thickness of the metal sheet can vary preferably from 0.5 mm to 0.7 mm. Thinner metal sheets can be used as long as they provide sufficient stiffness. Thin metal substrates produce a small amount of burrs during dicing and have a distinct advantage in laser cutting. In an exemplary embodiment, the metal sheet is made of, but is not limited to, aluminum, copper, tungsten, or molybdenum. For simple processing by using standard semiconductor tools, these substrates are cut in the shape of Si wafers with diameters ranging from 100 mm to 300 mm.

At step 606, metal substrate 202 undergoes mechanical burring around the edges to remove the burr created during laser cutting. Since these substrates are cut from metals with a standard-rolled surface (also known as mill finish), they have an average roughness typically in the order of a few microns. The metal substrate may be cut into wafer shapes with its flats determined by Semiconductor Equipment and Materials International (SEMI) standards and may be further smoothened by polishing it to a 32 rms finish (about 1 micron surface roughness).

Metal substrate 202 undergoes annealing at step 608, and temperature cycling at step 610 to remove the residual stresses. In accordance with an embodiment, the temperature during annealing of an aluminum substrate in the presence of vacuum is in the range of 350 to 400 degrees centigrade. During annealing, metal substrate 202 is pressed at pressures in the range of one to four kPa between two flat surfaces, which prohibit grain growth in the vertical direction. After two to three hours of annealing at a high temperature, the substrate is slowly ramped down to room temperature. This cycle can be repeated to orient the grains in the substrate and remove all the residual stresses. This tempering process prevents warping or bending of the substrates in the later stages of the process.

At step 612, metal substrate 202 undergoes a processing step to smoothen the surface in the preparation of the thin film deposition. In accordance with one embodiment, the smoothening step can be a diamond-turning process. Alternative polishing techniques, such as rubbing the metal surface with fine abrasives, followed by buffing to produce a mirror-finished surface can also be used. In accordance with another embodiment involving copper and tungsten substrates, smoothening can be performed by the CMP process. CMP, a well-established technique in semiconductor fabrication, uses abrasive chemical slurry in conjunction with a polishing pad to create smooth metal surfaces. The method ends at step 614.

FIG. 7 is a flow chart illustrating a method for depositing thermoelectric film 204 on metal substrate 202, in accordance with various embodiments of the present invention.

The method starts at step 702. At step 704, a thin thermoelectric film is deposited over metal substrate 202, which may have a thin refractory layer for adhesion. The adhesive layer and the thin film can be sequentially deposited in-situ in the same deposition chamber, thereby creating a clean interface between the film and the substrate. The deposition process is one of, but is not limited to, plasma vapor deposition sputtering, electroplating, molecular-beam epitaxy, and metal-organic chemical vapor deposition. While molecular beam epitaxy has been used to deposit high-quality super-lattice films, a major drawback of this technique is its slow throughput and high installation costs in commercial applications. Alternatively, sputtering and electroplating are two techniques where large substrates can be covered at a very high throughput. In an exemplary embodiment, the thin thermoelectric film is a bismuth chalcogenide, whose typical examples include, but are not limited to, Bi0.5Sb1.5Te3, Bi2Te3, Bi2Se3, and KBiTe3. In another exemplary embodiment, the thin thermoelectric film is a lead chalcogenide, whose examples include, but are not limited to, PbTe, PbEuTe and PbSnTe. Other varieties of thin films that can be deposited include YbAl3, CeAl3, InSb, SiGe, HgCdTe; and skutteridites that include, but are not limited to, CoSb3, and Fe0.2Co0.8Sb3. Recently, silicon nano-wires have shown interesting thermoelectric properties that can also be incorporated in the metal substrates.

There is a distinct advantage relating to the performance of the thermoelectric device when different types of thermoelectric films are layered together. Examples of p-type layered structure include, but are not limited to, Bi(0.5)Sb(1.5)Te(3)/Al/KBiTe(3), Bi(0.5)Sb(1.5)Te(3)/Al/Bi(0.5)Sb(1.5)Te(3), Pt/Bi(0.5)Sb(1.5)Te(3)/Pt, and the like. Similar examples of novel n-type layered structure include, but are not limited to, YbAl (3)/Bi(2)Te(3)/YbAl (3), Bi(2)Se(0.3)Te(2.7)/Al/Bi(2)Se(0.3)Te(2.7), Bi(2)Te(3)/Al/PbTe, InSb/Al/Bi(2)Te(3), and the like. Thicknesses of such layered structure can vary from 0.01 micrometer to 10 micrometer. Multiple thermoelectric layers can reduce the thermal conductivity of the thermoelement and provide a smooth gradient for a change in the Seebeck coefficient at the interfaces. In an exemplary embodiment, a single 0.5 micron layer of a p-type thermoelectric film Bi(0.5)Sb(1.5)Te(3) sputter deposited on a thin TiW at 290 degrees centigrade and 5 mTorr pressure exhibits a Seebeck coefficient of 240 microVolt/K and an electrical conductivity of 0.025 siemens/micrometer. Similar thickness of an n-type thermoelectric film Bi(2)Te(3) sputter coated on thin TiW at 330° C. and 20 mTorr pressure, exhibits a Seebeck coefficient of −190 microVolt/K and an electrical conductivity of 0.05 S/micrometer.

At step 706, barrier layer 218 is deposited on thermoelectric film 204 to prevent oxidation of the film surface. Barrier layer 218 can be one of, but is not limited to, metals such as Pt, Al, Ni, Ti, and chromium (Cr). At step 708, thermoelectric film 204 is subjected to annealing in vacuum or an inert atmosphere. In accordance with an embodiment, the annealing temperature is in the range of 300 to 350 degrees centigrade, and the anneal time is typically between 2 and 3 hours. Annealing improves the Seebeck coefficient and the electrical conductivity of the thermoelectric film. Further, annealing creates smaller and homogeneous grains in the presence of barrier layer 218. The method ends at step 710.

The thermoelectric cooling device of the present invention has many advantages. In various embodiments of the present invention, the thermoelectric cooling device includes thin film thermoelectric films that exhibit improved performance and efficiency, as compared with bulk materials. Thin film thermoelectric coolers can achieve high cooling densities, provide fast time response, and use less thermoelectric materials to achieve efficient cooling. Further, a wide variety of materials can be deposited either individually or layered together to create thin films with improved values of ZT.

In various embodiments of the present invention, the thermoelectric cooling device includes a metal substrate that simplifies the process of managing high heat fluxes. Further, minimizing the number of interfaces between the heat sink and the cooling plate improves the performance of these devices.

In various embodiments of the present invention, the thermoelectric cooling device includes one or more bumps. These bumps control the electrical and thermal resistances of the thermoelectric film, thereby tailoring the films for various applications. By varying the bump geometry, the same film can be used to create high temperature differences and low heat flux or vice versa.

Conventionally, the method for creating a thermoelectric cooling device involves extensive use of techniques used for etching and patterning. These processes usually degrade the quality of the film by introducing corrosive chemicals, contaminating the film surface with inorganic residues, and in some cases oxidizing the film surface. The method for creating the thermoelectric cooling device, in accordance with the present invention, makes minimal use of the techniques used for etching and patterning.

The thermoelectric cooling device has a low packaging complexity and can be designed in various shapes and cooling densities. In the embodiments described herein, the thermoelectric cooling devices are shown in vertical configurations. The most significant advantage of the design lies in the flexibility of incorporating any high quality thermoelectric film that can be deposited on a metal surface. By removing etching and patterning steps, and by controlling the current flow by using metal bumps, the design provided in the present invention enables the creation of feasible cooler devices from thermoelectric films.

While the preferred embodiments of the thermoelectric device in this invention have been discussed with reference to the cooling applications, the same embodiments can be used for reciprocal power generation applications, such as recovery of waste-heat or generating electricity from the infrared solar radiation, or in conjunction with photovoltaic cells to capture energy from the solar radiation spectrum.

While the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention.

What is claimed is:

1. A thermoelement for use in thermoelectric coolers comprising:
a metal substrate capable of dissipating heat;
one or more thermoelectric films, the one or more thermoelectric films being present on the metal substrate; and
one or more bumped structures present on the one or more thermoelectric films, the one or more bumped structures having a cross-section area configured to provide a predefined electrical and thermal resistance to the thermoelement.

2. The thermoelement of claim 1, wherein at least one of the one or more thermoelectric films is a thin thermoelectric film.

3. The thermoelement of claim 1, wherein the cross-section area of the one or more bumped structures is configured to provide a predefined current for cooling.

4. The thermoelement of claim 1, wherein the one or more thermoelectric films are made of a material selected from the group consisting of Bismuth Chalcogenides, Lead Chalcogenides, YbAl₃, CeAl₃, InSb, HgCdTe, Skutteridites, Silicon, and SiGe.

5. The thermoelement of claim 1, wherein the one or more thermoelectric films comprise one or more p-type films.

6. The thermoelement of claim 5, wherein the one or more p-type films comprise one or more of Bi_{0.5}Sb_{1.5}Te₃, and KBiTe₃.

7. The thermoelement of claim 1, wherein the one or more thermoelectric films comprise one or more n-type films.

8. The thermoelement of claim 7, wherein the one or more n-type films comprise one or more of YbAl₃, Bi₂Se_{0.3}Te_{2.7}, PbTe, and InSb.

9. The thermoelement of claim 1, wherein the thermoelement further comprises a barrier layer present between the one or more thermoelectric films and the one or more bumped structures.

10. The thermoelement of claim 1, wherein the one or more bumped structures are coated with a solder layer.

11. A thermoelectric cooling device comprising:
a first part comprising a first layer made of a thermally conducting and electrically insulating material and a second layer that is thermally and electrically conducting;
a second part comprising a third layer made of a thermally conducting and electrically insulating material and a fourth layer that is thermally and electrically conducting; and
at least one thermoelement present between the first part and the second part, the thermoelement comprising:
a metal substrate capable of dissipating heat;
one or more thermoelectric films, the one or more thermoelectric films being present on the metal substrate; and
one or more bumped structures present on the one or more thermoelectric films, the one or more bumped structures having a cross-section area configured to provide a predetermined electrical and thermal resistance to the thermoelement.

12. The thermoelectric cooling device of claim 11, wherein the one or more thermoelectric films comprise a p-type film alternated by an n-type film.

13. A method for manufacturing a thermoelement comprising the steps of:
depositing one or more thermoelectric films on a metal substrate; and
plating one or more bumped structures on the one or more thermoelectric films, the one or more structures having a cross-section area configured to provide a predetermined electrical and thermal resistance to the thermoelement.

14. The method of claim 13 further comprising laser cutting the metal substrate.

15. The method of claim 13 further comprising burring and smoothing the metal substrate.

16. The method of claim 13 further comprising annealing the metal substrate.

17. The method of claim 13, wherein the step of depositing the one or more thermoelectric films on the metal substrate comprises one or more of plasma vapor deposition, e-beam sputtering, electroplating, molecular-beam epitaxy, and metal-organic chemical vapor deposition.

18. The method of claim 13, wherein the method further comprises annealing the one or more thermoelectric films.

19. The method of claim 13, wherein the step of depositing the one or more thermoelectric films on the metal substrate comprises depositing a p-type film and an n-type film.

20. The method of claim 13, wherein the one or more bumped structures are plated on the one or more thermoelectric films by electroplating.

21. The method of claim 13 further comprising singularizing the thermoelement by etching of the metal substrate.

22. The method of claim 13 further comprising singularizing the thermoelement by dicing of the metal substrate.

23. The method of claim 13 further comprising singularizing the thermoelement by stamping of the metal substrate.
